(19) United States
(12) Patent Application Publication
(10) Pub. No.: US 2007/0108477 A1
(43) Pub. Date: May 17, 2007

(54) SEMICONDUCTOR STRUCTURE

(76) Inventors: Tsun-Lai Hsu, Hsinchu Hsien (TW); Yu-Chia Chen, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,937

(22) Filed: Nov. 4, 2005

(51) Int. Cl. H01L 29/768; H01L 27/148

(52) U.S. Cl. 257/244

(57) ABSTRACT

A semiconductor structure comprising a first conductive type substrate, a first conductive type well, an integrated circuit region, an isolation structure and a second conductive type doped region is described. The first conductive type well is disposed in the first conductive type substrate. The integrated circuit region is disposed in the first conductive type well. The isolation structure is disposed in the first conductive type substrate around the integrated circuit region. The second conductive type doped region is disposed in the first conductive type substrate around the isolation structure.

### BACKGROUND OF THE INVENTION

1. Field of the Invention

The present invention relates to a semiconductor structure. More particularly, the present invention relates to a semiconductor structure that can prevent noise interference.

2. Description of the Related Art

In very large scale integration (VLSI) and ultra large scale integration (ULSI) circuits, distance between integrated circuits are getting closer and closer to each other. As a result of the capacitive coupling between neighboring integrated circuits, noises or cross talk signals are frequently produced. With the continual reduction in the feature size of integrated circuits, their critical dimension also get smaller. Therefore, the intensity of capacitive coupling and noise between neighboring integrated circuits will intensify.

FIG. 1 is a top view of a conventional semiconductor structure, and FIG. 2 is a cross-sectional view along line A-A′ of FIG. 1. As shown in FIGS. 1 and 2, the P-type substrate 100 has a P-type well 102, an integrated circuit region 104, an isolation structure 106, an N-type well 108 and an N-type deep well 110. At present, the most commonly used design for isolating noise includes setting up a guard ring made from the N-type region 108 or utilizing the N-type deep well 110 underneath the integrated circuit region formed outside the integrated circuit region 106.

However, operating at a frequency higher than 10 GHz, a junction capacitance between the N-type well 108 and the P-type well 102, between the N-type deep well 110 and P-type substrate 100, between the N-type well 108 and P-type substrate 100 and between the N-type deep well 110 and the P-type deep well 102 is easily formed. Therefore, the noise may couple with the integrated circuit region 106 through the junction capacitance produced by the P-type substrate 100. Ultimately, this may cause an average increase in the noise level of the integrated circuit region 106 or lead to disturbances that can forestall the operation of the integrated circuit.

### SUMMARY OF THE INVENTION

Accordingly, at least one objective of the present invention is to provide a semiconductor structure that can effectively keep out noise signals so that noise is prevented from infiltrating into an integrated circuit region.

At least a second objective of the present invention is to provide a semiconductor structure that can prevent an integrated circuit from subjecting to noise interference.

To achieve these and other advantages and in accordance with the purpose of the invention, as embodied and broadly described herein, the invention provides a semiconductor structure. The semiconductor structure comprises a first conductive type substrate, a first conductive type well, an integrated circuit region, an isolation structure and a second conductive type doped region is described. The first conductive type well is disposed in the first conductive type substrate. The integrated circuit region is disposed in the first conductive type well. The isolation structure is disposed in the first conductive type substrate around the integrated circuit region. The second conductive type doped region is disposed in the first conductive type substrate around the isolation structure.

According to one preferred embodiment of the present invention, the aforementioned semiconductor structure further includes a second conductive type well disposed in the first conductive type substrate around the isolation structure. Furthermore, the second conductive type doped region is disposed in the second conductive type well.

According to one preferred embodiment of the present invention, the second conductive type doped region of the aforementioned semiconductor structure has a dopant concentration higher than the second conductive type well.

According to one preferred embodiment of the present invention, the second conductive type doped region of the aforementioned semiconductor structure is electrically connected to a preset voltage.

According to one preferred embodiment of the present invention, the preset voltage for the aforementioned semiconductor structure includes a ground connection.

According to one preferred embodiment of the present invention, the isolation structure of the aforementioned semiconductor structure includes a shallow trench isolation (STI) structure.

The present invention also provides an alternative semiconductor structure. The semiconductor structure comprises a first conductive type substrate, a first conductive type well, an integrated circuit region, an isolation structure; a second conductive type doped region, a second conductive type well and a second conductive type deep well. The first conductive type well is disposed in the first conductive type substrate. The integrated circuit region is disposed on the first conductive type well. The isolation structure is disposed in the first conductive type substrate around the integrated circuit region. The second conductive type well is disposed in the first conductive type substrate around the isolation structure. The second conductive type doped region is disposed in the second conductive type well around the isolation structure. The second conductive type deep well is disposed in the first conductive type substrate under the first conductive type well and connected to the second conductive type well.

According to one preferred embodiment of the present invention, the second conductive type doped region in the aforementioned semiconductor structure has a dopant concentration greater than the second conductive type well.

According to one preferred embodiment of the present invention, the second conductive type doped region in the aforementioned semiconductor structure is electrically connected to a preset voltage.

According to one preferred embodiment of the present invention, the preset voltage for the aforementioned semiconductor structure includes a ground connection.

According to one preferred embodiment of the present invention, the isolation structure of the aforementioned semiconductor structure includes a shallow trench isolation (STI) structure.

In the present invention, the semiconductor structure has a guard ring built using the second conductive type doped region so that noise signals are effectively shielded from the integrated circuit region. Thus, the integrated circuit can operate in a stable state. In addition, the second conductive type doped region in the semiconductor structure of the present invention can keep out most of the noise signals so that the amount of noise reaching the integrated circuit region through junction capacitance coupling is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of a conventional semiconductor structure.

FIG. 2 is a cross-sectional view along line A-A′ of FIG. 1.

FIG. 3 is a top view of a semiconductor structure according to one preferred embodiment of the present invention.

FIG. 4 is a cross-sectional view along line B-B′ of FIG. 3.

FIG. 5 is a top view of a semiconductor structure according to another preferred embodiment of the present invention.

FIG. 6 is a cross-sectional view along line C-C′ of FIG. 5.

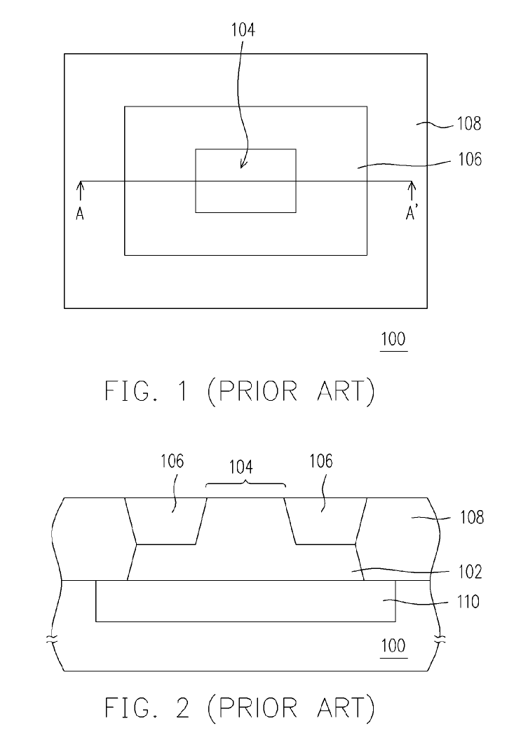

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

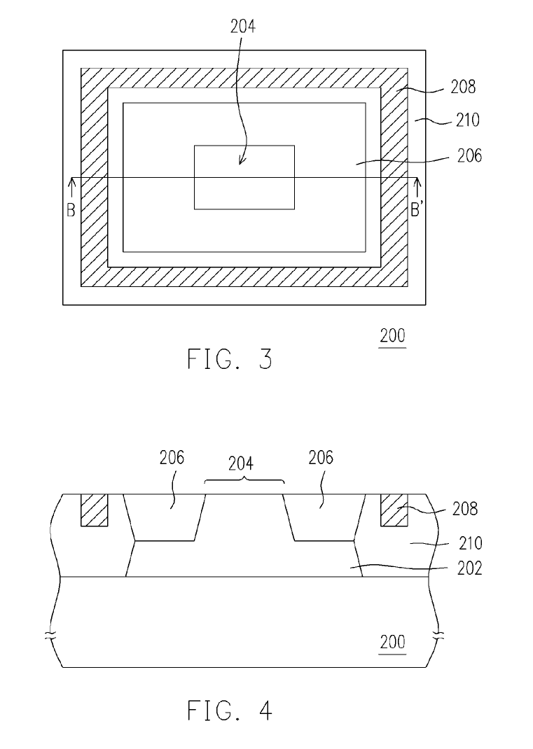

FIG. 3 is a top view of a semiconductor structure according to one preferred embodiment of the present invention. FIG. 4 is a cross-sectional view along line B-B′ of FIG. 3. As shown in FIGS. 3 and 4, the semiconductor structure comprises a first conductive type substrate 200, a first conductive type well 202, an integrated circuit region 204, an isolation structure 206 and a second conductive type doped region 208.

The first conductive type substrate 200 is a P-type silicon substrate, for example.

The first conductive type well 202 is disposed in the first conductive type substrate 200. The first conductive type well 202 is a P-type well region, for example. The method of forming the first conductive type well 202 includes performing an ion implant process on the silicon substrate using boron as the dopants, for example.

The integrated circuit region 204 is disposed on the first conductive type well 202. The integrated circuit region 204 is an area with patterned integrated circuit (not shown). The integrated circuits within the integrated circuit region 204 comprise circuit devices including resistors, capacitors, inductors or metal-oxide-semiconductor (MOS) transistors, for example. In fact, anyone familiar with the knowledge in this field should notice that the integrated circuits could be a memory circuit, a digital-to-analogue converter circuit or an analogue/digital converter circuit. Hence, a detailed description is omitted.

The isolation structure 206 is disposed in the first conductive type substrate 200 around the integrated circuit region 204 for isolating the integrated circuit region 204 and other semiconductor devices or integrated circuit regions on the first conductive type substrate 200. The isolation structure 206 is a shallow trench isolation (STI) structure fabricated using silicon oxide material, for example.

The second conductive type doped region 208 is disposed in the first conductive type substrate 200 around the isolation structure 206. The second conductive type doped region 208 is an N-doped region, for example. The second conductive type doped region 208 is formed, for example, by performing an ion implant process using phosphorus as the dopants. The second conductive type doped region 208 is electrically connected to a preset voltage and the preset voltage is a ground connection, for example.

In addition, a second conductive type well 210 may also be disposed in the first conductive type substrate 200. Furthermore, the second conductive type well 210 surrounds the isolation structure 206. The second conductive type well 210 is an N-type well region, for example. The method of forming the second conductive type well 210 includes performing an ion implant process using phosphorus as the dopants, for example. The second conductive type doped region 208 has a dopant concentration higher than the second conductive well 210.

Because the semiconductor structure includes a guard ring formed from the second conductive type well 210 and another guard ring formed from the second conductive type doped region 208, the integrated circuit region 204 is effectively protected against noise interference. Furthermore, the second conductive type doped region 208 provides a shield for most of the noise signals. Therefore, the coupling of noise to the integrated circuit region 206 through the junction capacitance produced by the first conductive type substrate 200 is minimized.

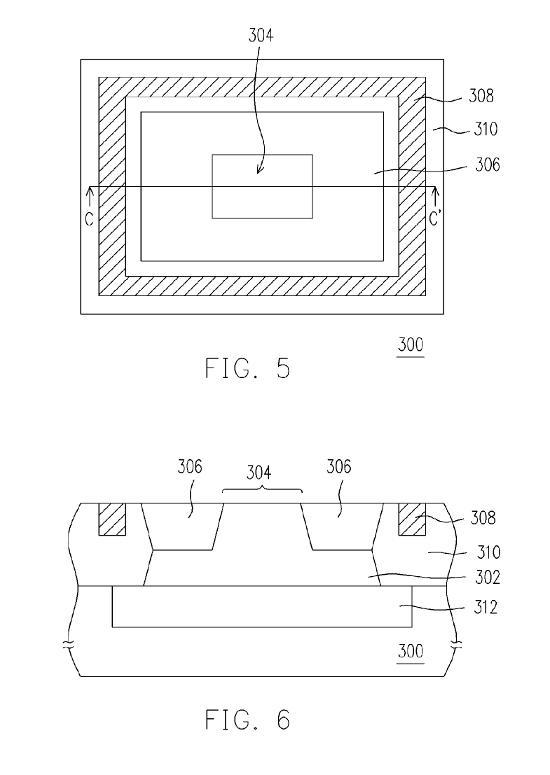

FIG. 5 is a top view of a semiconductor structure according to another preferred embodiment of the present invention. FIG. 6 is a cross-sectional view along line C-C′ of FIG. 5. As shown in FIGS. 5 and 6, the semiconductor structure comprises a first conductive type substrate 300, a first conductive type well 302, an integrated circuit region 304, an isolation structure 306, a second conductive type doped region 308, a second conductive type well 310 and a second conductive type deep well 312.

The first conductive type substrate 300 is a P-type silicon substrate, for example.

The first conductive type well 302 is disposed in the first conductive type substrate 300. The first conductive type well 302 is a P-type well region, for example. The method of forming the first conductive type well 302 includes performing an ion implant process on the silicon substrate using boron as the dopants, for example.

The integrated circuit region 304 is disposed on the first conductive type well 302. The integrated circuit region 304 is an area with patterned integrated circuit (not shown). The integrated circuits within the integrated circuit region 304 comprise circuit devices including resistors, capacitors, inductors or metal-oxide-semiconductor (MOS) transistors, for example. In fact, anyone familiar with the knowledge in this field should notice that the integrated circuits could be a memory circuit, a digital-to-analogue converter circuit or an analogue/digital converter circuit. Hence, a detailed description is omitted.

The isolation structure 306 is disposed in the first conductive type substrate 300 around the integrated circuit region 304 for isolating the integrated circuit region 304 and other semiconductor devices or integrated circuit regions on the first conductive type substrate 300. The isolation structure 306 is a shallow trench isolation (STI) structure fabricated using silicon oxide material, for example.

The second conductive type well 310 is disposed in the first conductive type substrate 300 around the isolation structure 306. The second conductive type well 310 is an N-type well region, for example. The second conductive type well 310 is formed, for example, by performing an ion implant process using phosphorus as the dopants.

The second conductive type doped region 308 is disposed in the second conductive type well 310 around the isolation structure 306. The second conductive type doped region 308 is an N-doped region, for example. The second conductive type doped region 208 has a dopant concentration higher than the second conductive type well 310. The second conductive type doped region 308 is formed, for example, by performing an ion implant process using phosphorus as the dopants. The second conductive type doped region 308 is electrically connected to a preset voltage and the preset voltage is a ground connection, for example.

The second conductive type deep well 312 is disposed in the first conductive type substrate 300 under the first conductive type well 302 and electrically connected to the second conductive type well 310. The second conductive type deep well 312 is an N-type deep well, for example. The second conductive type deep well 312 is formed, for example, by performing an ion implant process using phosphorus as the dopants.

Because the semiconductor structure includes a guard ring formed from the second conductive type well 310 and another guard ring formed from the second conductive type deep well 312 and the second conductive type doped region 308, noise is virtually isolated and the infiltration of noise into the integrated circuit region 304 is effectively suppressed. Furthermore, the second conductive type doped region 308 provides a shield for most of the noise signals. Therefore, the coupling of noise to the integrated circuit region 306 through the junction capacitance produced by the first conductive type substrate 300 is minimized.

Although the first conductive type refers to a P-type and the second conductive type refers to an N-type in the aforesaid embodiment, anyone familiar with the technique in this field may notice that the reverse is equally applicable. In other words, the same method can be applied to form a semiconductor structure with the first conductive type being the N-type and the second conductive type being the P-type. Hence, a detailed description of this aspect of the invention not repeated.

In summary, major advantages of the present invention includes at least the followings.

1. Because the semiconductor structure of the present invention incorporates a guard ring fabricated through the second conductive type doped region, the integrated circuit is effectively shielded from against noise interference.

2. With the provision of an effective means of shielding the semiconductor structure against noise, the integrated circuit can operate in a more stable condition.

3. Since the second conductive type doped region can isolate most of the noise signals, noise coupled to the integrated circuit through the junction capacitance is significantly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor structure, comprising:
a first conductive type substrate;
a first conductive type well disposed in the first conductive type substrate;
an integrated circuit region disposed on the first conductive type well;
an isolation structure disposed in the first conductive type substrate around the integrated circuit region; and
a second conductive type doped region disposed in the first conductive type substrate around the isolation structure.

2. The semiconductor structure of claim 1, further includes a second conductive type well disposed in the first conductive type substrate around the isolation structure such that the second conductive type doped region is disposed in the second conductive type well.

3. The semiconductor structure of claim 2, wherein the second conductive type doped region has a dopant concentration higher than the second conductive type well.

4. The semiconductor structure of claim 1, wherein the second conductive type doped region is electrically connected to a preset voltage.

5. The semiconductor structure of claim 4, wherein the preset voltage includes a ground connection.

6. The semiconductor structure of claim 1, wherein the isolation structure includes a shallow trench isolation (STI) structure.

7. A semiconductor structure, comprising:
a first conductive type substrate;
a first conductive type well disposed in the first conductive type substrate;
an integrated circuit region disposed on the first conductive type well;
an isolation structure disposed in the first conductive type substrate around the integrated circuit region;
a second conductive type well disposed in the first conductive type substrate around the isolation structure;
a second conductive type doped region disposed in the second conductive type well around the isolation structure; and
a second conductive type deep well disposed in the first conductive type substrate under the first conductive type well and connected to the second conductive type well.

8. The semiconductor structure of claim 7, wherein the second conductive type doped region has a dopant concentration greater than the second conductive type well.

9. The semiconductor structure of claim 7, wherein the second conductive type doped region is electrically connected to a preset voltage.

10. The semiconductor structure of claim 9, wherein the preset voltage includes a ground connection.

11. The semiconductor structure of claim 7, wherein the isolation structure includes a shallow trench isolation (STI) structure.
